(19) United States
(12) Patent Application Publication
(10) Pub. No.: US 2013/0107475 A1
(43) Pub. Date: May 2, 2013

(54) FLEXIBLE CIRCUIT BOARD STACK ASSEMBLY

(71) Applicants: MING-CHUN HSIEH, Shindian (TW); CHANG-SHIUN YANG, Shindian (TW); CHUN-WEI WU, Shindian (TW); HE-LONG WU, Shindian (TW); REN-CHING HUA, Shindian (TW); CHUN-YING HUANG, Shindian (TW)

(72) Inventors: MING-CHUN HSIEH, Shindian (TW); CHANG-SHIUN YANG, Shindian (TW); CHUN-WEI WU, Shindian (TW); HE-LONG WU, Shindian (TW); REN-CHING HUA, Shindian (TW); CHUN-YING HUANG, Shindian (TW)

(73) Assignee: FIH (HONG KONG) LIMITED, Kowloon (HK)

(21) Appl. No.: 13/309,706

(22) Filed: Dec. 2, 2011

(30) Foreign Application Priority Data
Oct. 27, 2011 (TW) 100220216

(51) Int. Cl. H05K 1/14

(52) U.S. Cl. 361/749

(57) ABSTRACT

A FCB stack assembly includes a PCB, a shield can, and a FCB. The shield can is fixed on the PCB for receiving and shielding electronic components on the PCB. The FCB is fixed onto and directly supported by the shield can.

### BACKGROUND

1. Technical Field

The disclosure generally relates to flexible circuit board (FCB) stack assemblies.

2. Description of Related Art

Flexible circuit boards (FCBs) are easy to bend but can be attached reinforcing boards when desired to prevent bending of the FCBs. An FCB and a board may be directly mounted onto a shield can of a printed circuit board (PCB). However, this arrangement greatly increases the volume of the PCB.

Therefore, there is room for improvement within the art.

### BRIEF DESCRIPTION OF THE DRAWINGS

Many aspects of the present disclosure can be better understood with reference to the following drawings. The elements in the drawings are not necessarily drawn to scale, the emphasis instead being placed upon clearly illustrating the principles of the disclosure.

FIG. 1 is an assembled, schematic view of one embodiment of a FCB stack assembly mounted on a PCB.

FIG. 2 is a disassembled perspective view of the FCB stack assembly shown in FIG. 1.

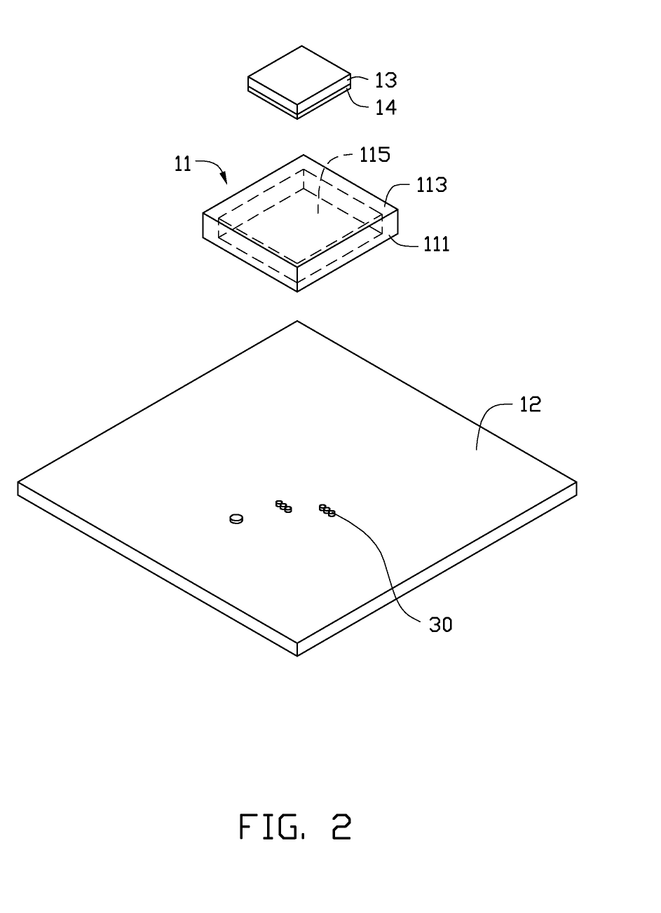

### DETAILED DESCRIPTION

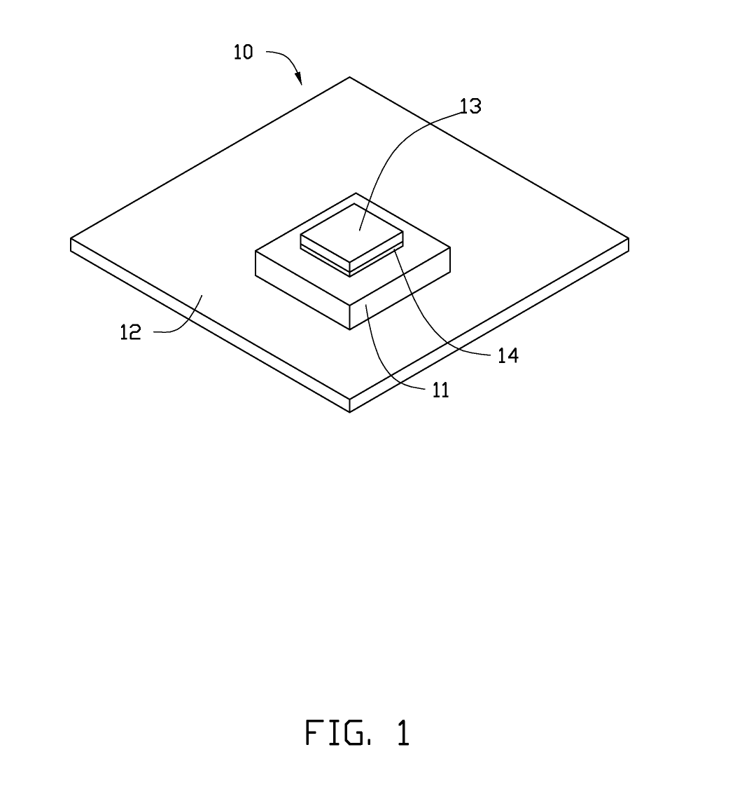

FIG. 1 shows an exemplary flexible circuit board (FCB) stack assembly 10 including a shield can 11, a printed circuit board (PCB) 12, and a FCB 13. The shield can 11 is positioned on the PCB 12 and supports the FCB 13.

The shield can 11 is made of a metal and includes a frame 111 and a top wall 113. The top wall 113 is perpendicularly connected to the frame 111, and thus a shield space 115 for receiving and shielding electronic components is defined by the top wall 113 and the frame 111.

The FCB 13 is fixed onto and directly supported by the top wall 113. Thus, unwanted bending of the FCB 113 is prevented without the use of a separate reinforcing board.

To assemble the FCB stack assembly the following steps may be performed:

Fix the shield can 11 on the PCB 12.

Fix the FCB 13 on the top wall 113, with a connector (not shown) of the FCB 13 against the top wall 13. In this exemplary embodiment, the FCB 13 is adhered to the top wall 13.

The FCB 13 of the FCB stack assembly 10 is fixed onto and directly supported by the top wall 113, thus unwanted bending of the FCB 113 is prevented without the use of a separate reinforcing board. The exemplary embodiment of the FCB stack assembly 10 has simple structure, reduces costs, and occupies less space.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A FCB stack assembly, comprising:
a PCB;
a shield can mounted on the PCB for receiving and shielding electronic components on the PCB; and
a FCB fixed onto and directly supported by the shield can.

2. The FCB stack assembly of claim 1, wherein the FCB is adhered on the shield can.

3. The FCB stack assembly of claim 1, wherein the shield can comprises a frame and a top wall perpendicularly connects the frame, the FCB is directly fixed onto the top wall.

4. The FCB stack assembly of claim 3, wherein the shield can further comprises a shield space defined by the frame and the top wall, for receiving and shielding electronic components, and the shield space is sealed by the PCB.
